(19) United States
(12) Patent Application Publication
(10) Pub. No.: US 2016/0100239 A1
(43) Pub. Date: Apr. 7, 2016

(54) SYSTEM FOR REPRODUCING SOUND

(71) Applicant: Electronics and Telecommunications Research Institute, Daejeon (KR)

(72) Inventors: Sung-Yong SHIN, Daejeon (KR); Bae-Sun KIM, Daejeon (KR); Jong-Moo SOHN, Daejeon (KR); Hyung-Cheol SHIN, Daejeon (KR); Hyun-Tae JEONG, Daejeon (KR)

(21) Appl. No.: 14/876,061

(22) Filed: Oct. 6, 2015

(30) Foreign Application Priority Data
Oct. 6, 2014 (KR) 10-2014-0134564

(51) Int. Cl. H04R 1/10; H03G 3/30

(52) U.S. Cl. CPC H04R 1/1016; H04R 1/1041; H03G 3/3005; H04R 2420/07

(57) ABSTRACT

A system for reproducing a sound in accordance with an embodiment of the present invention includes: a sound reproducing device configured to generate an audio signal corresponding to acoustic data and to allow the audio signal to be carried through a human body; and an earphone configured to output a sound by being vibrated by static electricity generated according to the audio signal carried through the human body.

### CROSS-REFERENCE TO RELATED APPLICATIONS

This application claims priority to and the benefit of Korean Patent Application No. 10-2014-0134564, filed with the Korean Intellectual Property Office on Oct. 6, 2014, the disclosure of which is incorporated herein by reference in its entirety.

### BACKGROUND

1. Technical Field

The present invention relates to reproducing a sound, more specifically to reproducing a sound through an earphone requiring no electric power.

2. Background Art

A representative wireless personal sound technology is Bluetooth earphones, which require electric power and electric circuits in order to receive electric waves and reproduces the sound. These requirements limit the Bluetooth earphones from being smaller and lighter and eventually from providing a more comfortable fit. Moreover, as security settings, such as pairing, are essential for electric waves, those who are not very familiar with electronic devices find the setting and sharing quite inconvenient.

Furthermore, sound receiving devices need to have a battery installed therein and/or be charged in order to supply their own electric power and thus are inevitably heavy.

### SUMMARY

The present invention provides a system for reproducing a sound through an earphone that is operated using an electric current transmitted through a human body.

An aspect of the present invention provides a system for reproducing a sound that includes: a sound reproducing device configured to generate an audio signal corresponding to acoustic data and to allow the audio signal to be carried through a human body; and an earphone configured to output a sound by being vibrated by static electricity generated according to the audio signal carried through the human body.

The earphone may include: a conductor having one end surface thereof formed in a ring shape; and an insulator surrounding an outside of the conductor.

The conductor may be vibrated by an electrostatic attractive force generated between the conductor and a subcutaneous layer of the human body through which the audio signal is carried.

The sound reproducing device may include: a sound reproducing part configured to generate the audio signal corresponding to the acoustic data; and a sound transmitting part configured to transmit the audio signal to the human body after increasing a voltage of the audio signal and lowering an intensity of current of the audio signal below a predetermined value.

The sound transmitting part may include: an amplifier configured to amplify the voltage of the audio signal; a current limiter configured to lower an intensity of current of the voltage-amplified audio signal below a predetermined value; and an electrode configured to allow the audio signal having the intensity of current lowered below the predetermined value to be carried through the human body by being in contact with the human body.

The sound reproducing device may further include a power source configured to provide electric power, and the sound transmitting part may further include a boost converter configured to boost a voltage of the electric power to a predetermined value and supply the electric power to the amplifier.

Another aspect of the present invention provides a sound reproducing device that includes: a sound reproducing part configured to generate an audio signal corresponding to acoustic data; an amplifier configured to amplify a voltage of the audio signal; a current limiter configured to lower an intensity of current of the voltage-amplified audio signal below a predetermined value; and an electrode configured to allow the audio signal having the intensity of current lowered below the predetermined value to be carried through a human body by being in contact with the human body.

The sound reproducing device may further include: a power source configured to provide electric power; and a boost converter configured to boost a voltage of the electric power to a predetermined value and supply the electric power to the amplifier.

Yet another aspect of the present invention provides an earphone that includes: a conductor configured to be vibrated by an electrostatic attractive force generated between the conductor and a subcutaneous layer of a human body through which an audio signal is carried and having one end surface thereof formed in a ring shape; and an insulator surrounding an outside of the conductor.

The insulator may be made of silicon.

The present invention allows the earphone to be smaller and lighter by allowing the sound to be reproduced without electric power.

The present invention allows the sound to be reproduced through the earphone that does not require to be charged.

With the present invention, it is possible to transmit the audio signal that is harmless to the human body and not felt by a person through the human body.

### BRIEF DESCRIPTION OF DRAWINGS

FIG. 1 is a block diagram showing a system for reproducing a sound in accordance with an embodiment of the present invention.

FIG. 2 shows how an audio signal is transmitted through the system for reproducing a sound in accordance with an embodiment of the present invention.

FIG. 3 is a block diagram showing a sound reproducing device in the system for reproducing a sound in accordance with an embodiment of the present invention.

FIG. 4 show a human skin and an earphone of the system for reproducing a sound in accordance with an embodiment of the present invention.

FIG. 5 shows some examples of articles in which the sound reproducing device in accordance with an embodiment of the present invention can be installed.

FIG. 6 shows a terminal in which the sound reproducing device in accordance with an embodiment of the present invention is installed.

FIG. 7 shows a display in which the sound reproducing device in accordance with an embodiment of the present invention is installed.

### DETAILED DESCRIPTION

Since there can be a variety of permutations and embodiments of the present invention, certain embodiments will be illustrated and described with reference to the accompanying drawings. This, however, is by no means to restrict the present invention to certain embodiments, and shall be construed as including all permutations, equivalents and substitutes covered by the ideas and scope of the present invention.

Throughout the description of the present invention, when describing a certain technology is determined to evade the point of the present invention, the pertinent detailed description will be omitted. Numerals (e.g., first, second, etc.) used in the description of the present invention are only for distinguishing one element from another element.

When one element is described as being “connected” or “accessed” to another element, it shall be construed as being connected or accessed to the other element directly but also as possibly having another element in between. On the other hand, if one element is described as being “directly connected” or “directly accessed” to another element, it shall be construed that there is no other element in between.

Hereinafter, some embodiments will be described in detail with reference to the accompanying drawings. Identical or corresponding elements will be given the same reference numerals, regardless of the figure number, and any redundant description of the identical or corresponding elements will not be repeated. Throughout the description of the present invention, when describing a certain technology is determined to evade the point of the present invention, the pertinent detailed description will be omitted.

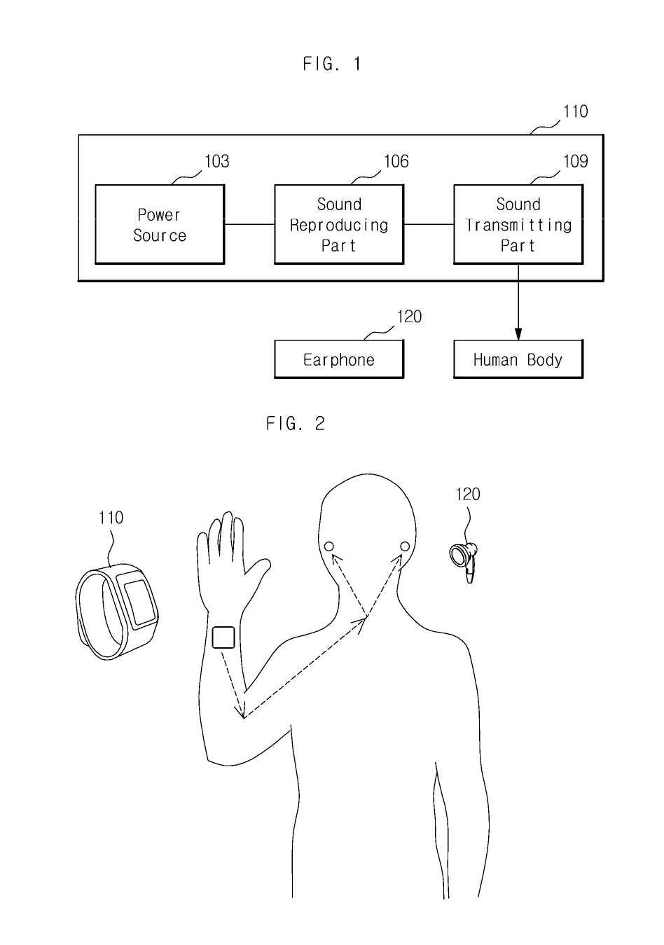

FIG. 1 is a block diagram showing a system for reproducing a sound in accordance with an embodiment of the present invention, and FIG. 2 shows how an audio signal is transmitted through the system for reproducing a sound in accordance with an embodiment of the present invention.

Referring to FIG. 1, the system for reproducing a sound in accordance with an embodiment of the present invention includes a sound reproducing device 110 and an earphone 120.

The sound reproducing device 110 transmits an electric signal based on acoustic data to human skin. The sound reproducing device 110 includes a power source 103, a sound reproducing part 106 and a sound transmitting part 109.

The power source 103, which is a module such as a batter, a power supply, etc., supplies a predetermined electric power to the sound reproducing part 106. The sound reproducing part 106 sends an audio signal, which is an electric signal based on acoustic data, to the sound transmitting part 109 and supplies the electric power supplied by the power source 103 to the sound transmitting part 109. Here, the audio signal may be an alternating current having an amplitude and frequency of a waveform thereof formed to correspond to an amplitude and frequency of a waveform that will be outputted according to the acoustic data. The acoustic data describes the sound through a known method, such as mp3. Here, the sound reproducing part 106 may have a storage medium, such as a memory, installed therein to pre-store the acoustic data therein or have a communication module installed therein to receive the acoustic data from an external device. Moreover, the sound reproducing part 106 may output the acoustic data as an audio signal through at least one of many known methods.

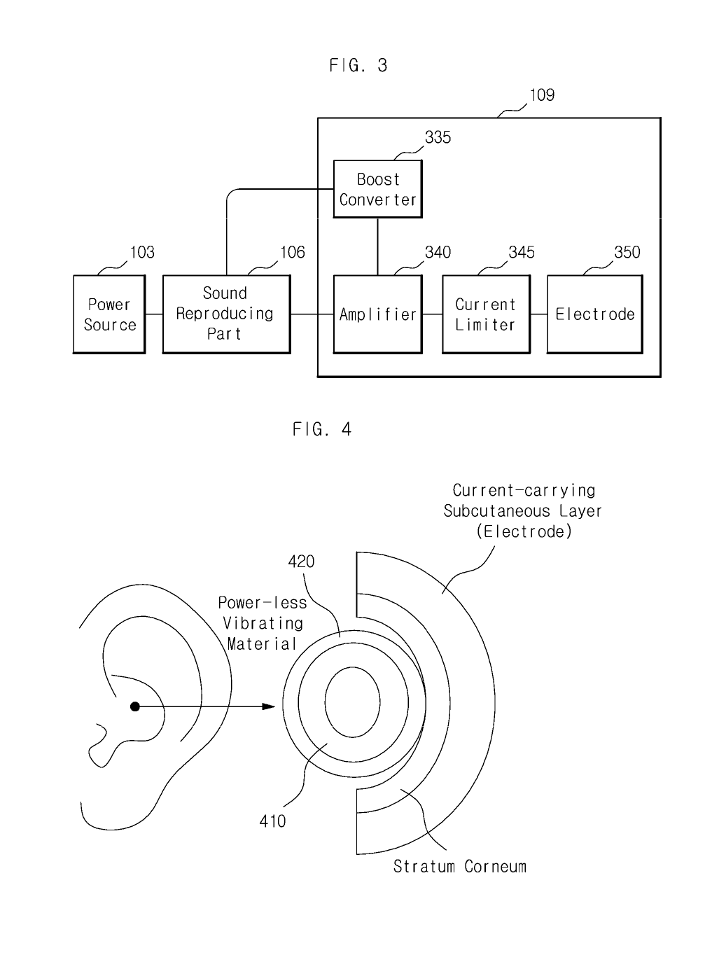

The sound transmitting part 109 amplifies the audio signal received from the sound reproducing part 106 by use of the electric power supplied by the sound reproducing part 106, and outputs the amplified audio signal to the human skin. Accordingly, as shown in FIG. 2, the audio signal, which is an electric signal, may be transmitted to a subcutaneous layer of the skin that is adjacent to the earphone 120 through the conductive human body. The detailed structure of the sound transmitting part 109 will be described later in detail with reference to FIG. 3. Moreover, although it is described that the power source 103 supplies the electric power to the sound reproducing part 106 only, it is also possible that the power source 103 supplies the electric power directly to the sound transmitting part 109 and that the sound reproducing device 110 transmits the audio signal only to the sound transmitting part 109, depending on how the present invention is embodied.

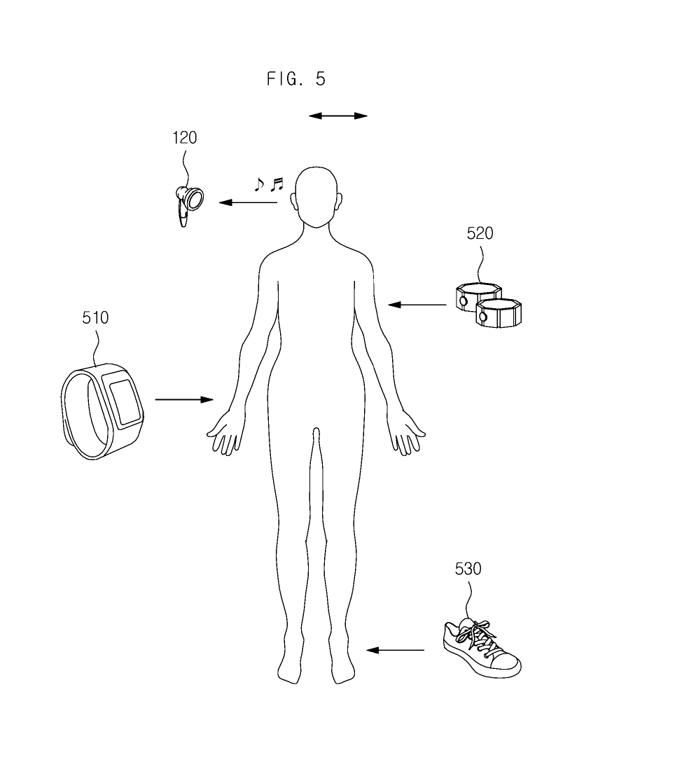

The earphone 120 includes a conductor having one end surface thereof formed in a ring shape and an insulator surrounding an outside of the conductor. Accordingly, the earphone 120 may generate sound waves by having the conductor vibrated according to the electric signal that is conducted to the subcutaneous layer of an ear. The principle of how the earphone is vibrated and the structure of the earphone will be described later in detail with reference to FIG. 4 and FIG. 5.

FIG. 3 is a block diagram showing a sound reproducing device in the system for reproducing a sound in accordance with an embodiment of the present invention.

The sound transmitting part 109 of the sound reproducing device 110 includes a boost converter 335, an amplifier 340, a current limiter 345 and an electrode 350.

The boost converter 335 boosts a voltage of the electric power supplied by the sound reproducing part 106 and supplies the electric power to the amplifier 340. Here, even if the current of the audio signal flows through the human body, the current is harmless to the human body and is not felt by a person only if the intensity of the current is weak enough (for example, 0.5 mA or less). Accordingly, any audio signal having an electric power that can be transmitted through the human body should be converted by the amplifier 340 to a signal having a high enough voltage and a low enough current in order for the audio signal to be harmless to the human body and not felt by the person. Therefore, the amplifier 340 requires a high voltage of electric power in order to covert the voltage of the audio signal. The boost converter 335 boosts the voltage of the electric power supplied by the sound reproducing part 106 to a predetermined value and supplies the electric power to the amplifier 340.

Here, the boost converter 335 may be realized through a plurality of known modules, for example, a step-up regulator, a fly-back converter, etc. For example, the boost converter 335 may include the step-up regulator, which amplifies the electric power supplied by the sound reproducing part 106, and the fly-back converter, which re-amplifies the voltage of the voltage-amplified electric power and supplies the electric power to the amplifier 340.

The amplifier 340 amplifies the voltage of the audio signal received from the sound reproducing device 110 to a predetermined value (e.g., 100V) by use of the electric power supplied by the boost converter 335 and supplies the audio signal to the current limiter 345. Accordingly, the audio signal outputted by the amplifier 340 may be converted to a signal having a high voltage and a low current value.

In case the current value of the audio signal received from the amplifier 340 is over a predetermined value (e.g., 0.5 mA), the current limiter 345 lowers the current value of the audio signal below the predetermined value. Here, the current limiter 345 may lower the current value of the audio signal below the predetermined value by use of a known circuit that provides a current-limiting resistance. The current limiter 345 transmits the audio signal to the electrode 350.

The electrode 350 allows the audio signal to be carried through the human body when the electrode 350 makes contact with the skin of the human body. Accordingly, the audio signal carried through the human body by the electrode 350 may be carried through a conductive material, such as the subcutaneous layer of the skin, and reach the subcutaneous layer that is adjacent to the earphone 120, as shown in FIG. 2.

FIG. 4 show a human skin and an earphone of the system for reproducing a sound in accordance with an embodiment of the present invention.

Referring to FIG. 4, the earphone 120 includes a conductor 410 having one end surface thereof formed in a ring shape and an insulator 420 surrounding the conductor 410. Here, the insulator 420 may be made of a thin and flexible material, such as silicon. As described with reference to FIG. 3, the audio signal generated through the sound reproducing device 110 may be carried through the human body and to the subcutaneous layer of an ear, which is a skin adjacent to the earphone 120. As the dry stratum corneum, which has an insulating property, and the insulator 420 have dielectric layers formed therein, respectively, intermittent attraction may be occurred due to static electricity between the conductor of the earphone 120 and the subcutaneous layer when the audio signal, which is an alternating current signal, is carried through the subcutaneous layer. Accordingly, the conductor 410 of the earphone 120 may be vibrated according to the audio signal, and sound waves may be generated by the vibration. As a result, a user wearing the earphone 120 may sense the sound through the sound waves caused by the generation.

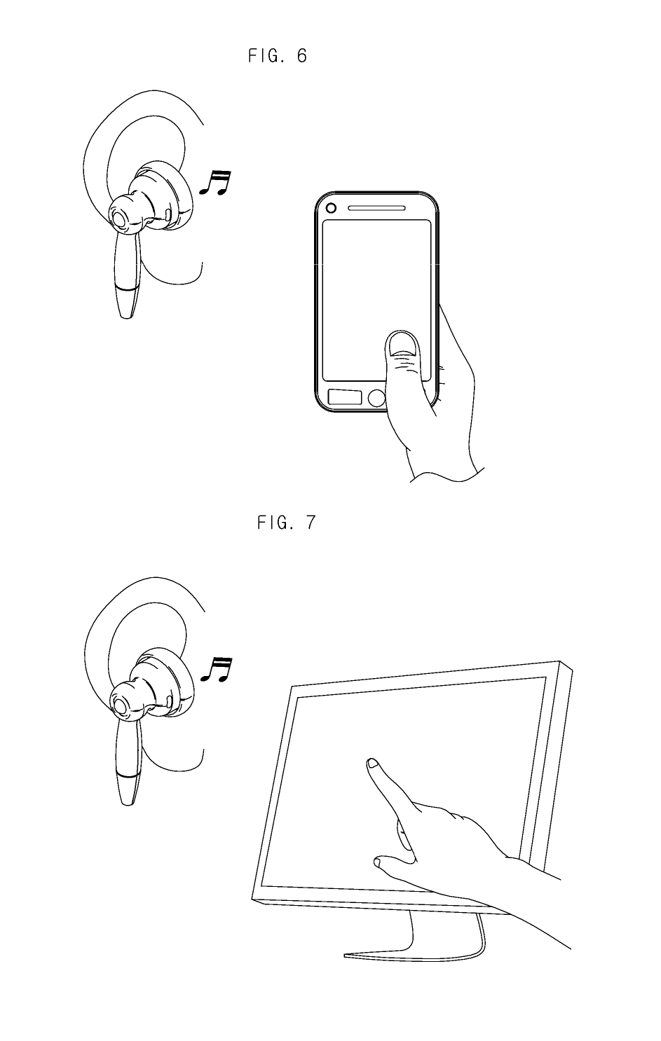

FIG. 5 shows some examples of articles in which the sound reproducing device in accordance with an embodiment of the present invention can be installed. FIG. 6 shows a terminal in which the sound reproducing device in accordance with an embodiment of the present invention is installed. FIG. 7 shows a display in which the sound reproducing device in accordance with an embodiment of the present invention is installed.

Referring to FIG. 5, the sound reproducing device may be installed in articles, such as a wrist watch 510, an arm band 520, a shoe 530, etc., which may be in direct contact with the human skin. Here, the sound reproducing device may have a communication interface installed therein so that an audio signal may be transmitted to the human body as described with reference to FIG. 3 in the case where acoustic data is received from an external device such as a smartphone or a signal requesting for reproduction of acoustic data pre-stored in the sound reproducing device is received.

Moreover, as illustrated in FIG. 6, the sound reproducing device may be embodied by being installed in a smartphone or in a smartphone case so that the audio signal may be transmitted through to the human body through a hand when the user holds the smartphone by the hand.

Moreover, as illustrated in FIG. 7, the sound reproducing device may be installed in the display so that the audio signal may be transmitted to a finger of a person touching a display screen through an electrode embedded in a lower layer of the display screen.

While the present invention has been described with reference to certain embodiments, the embodiments are for illustrative purposes only and shall not limit the invention. It is to be appreciated that those skilled in the art can change or modify the embodiments without departing from the scope and spirit of the invention.

What is claimed is:

1. A system for reproducing a sound, comprising:
a sound reproducing device configured to generate an audio signal corresponding to acoustic data and to allow the audio signal to be carried through a human body; and
an earphone configured to output a sound by being vibrated by static electricity generated according to the audio signal carried through the human body.

2. The system of claim 1, wherein the earphone comprises:
a conductor having one end surface thereof formed in a ring shape; and
an insulator surrounding an outside of the conductor.

3. The system of claim 2, wherein the conductor is vibrated by an electrostatic attractive force generated between the conductor and a subcutaneous layer of the human body through which the audio signal is carried.

4. The system of claim 1, wherein the sound reproducing device comprises:
a sound reproducing part configured to generate the audio signal corresponding to the acoustic data; and
a sound transmitting part configured to transmit the audio signal to the human body after increasing a voltage of the audio signal and lowering an intensity of current of the audio signal below a predetermined value.

5. The system of claim 4, wherein the sound transmitting part comprises:
an amplifier configured to amplify the voltage of the audio signal;
a current limiter configured to lower an intensity of current of the voltage-amplified audio signal below a predetermined value; and
an electrode configured to allow the audio signal having the intensity of current lowered below the predetermined value to be carried through the human body by being in contact with the human body.

6. The system of claim 5, wherein the sound reproducing device further comprises a power source configured to provide electric power, and
wherein the sound transmitting part further comprises a boost converter configured to boost a voltage of the electric power to a predetermined value and supply the electric power to the amplifier.

7. A sound reproducing device comprising:
a sound reproducing part configured to generate an audio signal corresponding to acoustic data;
an amplifier configured to amplify a voltage of the audio signal;
a current limiter configured to lower an intensity of current of the voltage-amplified audio signal below a predetermined value; and
an electrode configured to allow the audio signal having the intensity of current lowered below the predetermined value to be carried through a human body by being in contact with the human body.

8. The device of claim 7, further comprising:
a power source configured to provide electric power; and
a boost converter configured to boost a voltage of the electric power to a predetermined value and supply the electric power to the amplifier.

9. An earphone comprising:
a conductor configured to be vibrated by an electrostatic attractive force generated between the conductor and a subcutaneous layer of a human body through which an audio signal is carried and having one end surface thereof formed in a ring shape; and
an insulator surrounding an outside of the conductor.

10. The earphone of claim 9, wherein the insulator is made of silicon.
